(19) United States
(12) Patent Application Publication
(10) Pub. No.: US 2026/0157116 A1
(43) Pub. Date: Jun. 4, 2026

(54) SEMICONDUCTOR DEVICE AND METHOD FOR FABRICATING THE SAME

(71) Applicant: SK hynix Inc., Gyeonggi-do (KR)

(72) Inventor: Soo Man SEO, Gyeonggi-do (KR)

(21) Appl. No.: 19/248,493

(22) Filed: Jun. 25, 2025

(30) Foreign Application Priority Data
Dec. 3, 2024 (KR) 10-2024-0177216

(51) Int. Cl. H10N 50/10; G11C 11/16; H10N 50/01; H10N 50/85

(52) U.S. Cl. CPC H10N 50/10; G11C 11/161; H10N 50/01; H10N 50/85

(57) ABSTRACT

Disclosed is a semiconductor device and a method for fabricating the semiconductor device. The semiconductor device includes a plurality of first conductive lines extending in a first direction; a plurality of second conductive lines disposed over the first conductive lines and extending in a second direction intersecting with the first direction; and a plurality of memory cells respectively overlapping with intersection areas between the first conductive lines and the second conductive lines, wherein each of the memory cells includes a selector pattern and a Magnetic Tunnel Junction (MTJ) pattern which is disposed in an upper portion or a lower portion of the selector pattern, and wherein each of the second conductive lines is disposed between the MTJ patterns.

### CROSS-REFERENCE TO RELATED APPLICATIONS

The present application claims priority under 35 U.S.C 119a to Korean Patent Application No. 10-2024-0177216, filed on Dec. 3, 2024, which is incorporated herein by reference in its entirety.

### BACKGROUND

### 1. Field

Embodiments of the present disclosure relate generally to a semiconductor technology, and more particularly, to a semiconductor device including a Magnetic Tunnel Junction (MTJ) pattern and a selector pattern, and a method for fabricating the same.

### 2. Description of the Related Art

Recent demands for miniaturization, low power consumption, high performance, and diversification of electronic devices require semiconductor devices capable of storing data in diverse electronic devices, such as computers, portable communication devices and the like, and researchers and the industry are studying to develop such semiconductor devices. Such semiconductor devices include those capable of storing data by using the characteristics of switching between different resistance states according to the applied voltage or current, such as a Resistive Random Access Memory (RRAM), a Phase-change Random Access Memory (PRAM), a Ferroelectric Random Access Memory (FRAM), a Magnetic Random Access Memory (MRAM), an E-fuse and the like.

### SUMMARY

Embodiments of the present disclosure are directed to a semiconductor device that may effectively eliminate the possibility of electrical open failures by using an inter-layer dielectric layer having a high etching selectivity and forming a conductive line between Magnetic Tunnel Junction (MTJ) patterns.

In accordance with an embodiment of the present disclosure, a semiconductor device includes a plurality of first conductive lines extending in a first direction; a plurality of second conductive lines disposed over the first conductive lines and extending in a second direction intersecting with the first direction; and a plurality of memory cells respectively overlapping with intersection areas between the first conductive lines and the second conductive lines, wherein each of the memory cells includes a selector pattern and a Magnetic Tunnel Junction (MTJ) pattern which is disposed in an upper portion or a lower portion of the selector pattern, and wherein each of the second conductive lines is disposed between the MTJ patterns.

In accordance with another embodiment of the present disclosure, a method for fabricating semiconductor device includes forming a hard mask layer over a plurality of Magnetic Tunnel Junction (MTJ) patterns; forming a spacer pattern in an upper portion of the hard mask layer; forming a hard mask pattern by etching the hard mask layer with the spacer pattern used as an etching barrier; etching between the MTJ patterns by using the hard mask pattern as an etching barrier; and forming a conductive line by filling the etched portion between the MTJ patterns with a metal gap-fill material.

### BRIEF DESCRIPTION OF THE DRAWINGS

FIG. 1A is a top view illustrating a semiconductor device according to a comparative example.

FIGS. 1B and 1C are side views illustrating the semiconductor device according to the comparative example.

FIG. 2A is a top view illustrating a semiconductor device in accordance with an embodiment of the present disclosure.

FIG. 2B is a side view illustrating the semiconductor device in accordance with the embodiment of the present disclosure.

FIGS. 3A to 3I are side views illustrating a semiconductor device and a fabrication method thereof in accordance with an embodiment of the present disclosure.

FIG. 4 is a top view illustrating a semiconductor device in accordance with an embodiment of the present disclosure.

### DETAILED DESCRIPTION

Hereinafter, the various embodiments of the present disclosure will be described in detail with reference to the attached drawings.

Embodiments of the present disclosure will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout the disclosure, like reference numerals refer to like parts throughout the various figures and embodiments of the present disclosure.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

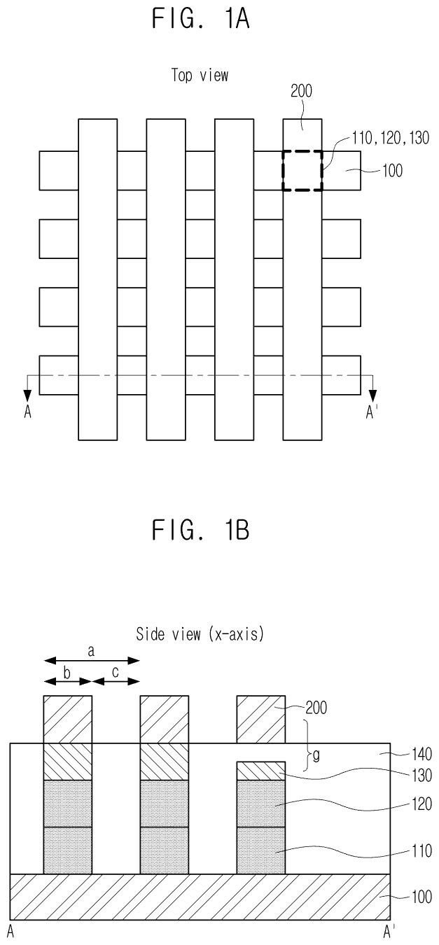

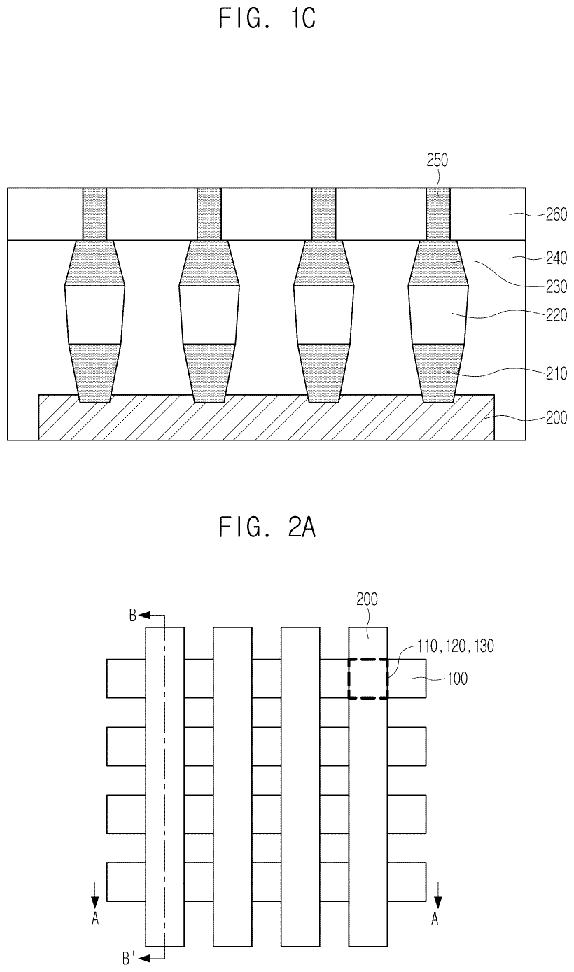

Before describing the semiconductor device in accordance with an embodiment of the present disclosure, a semiconductor device according to a comparative example is described first. FIGS. 1A to 1C show a top view and a side view of a semiconductor device according to a comparative example.

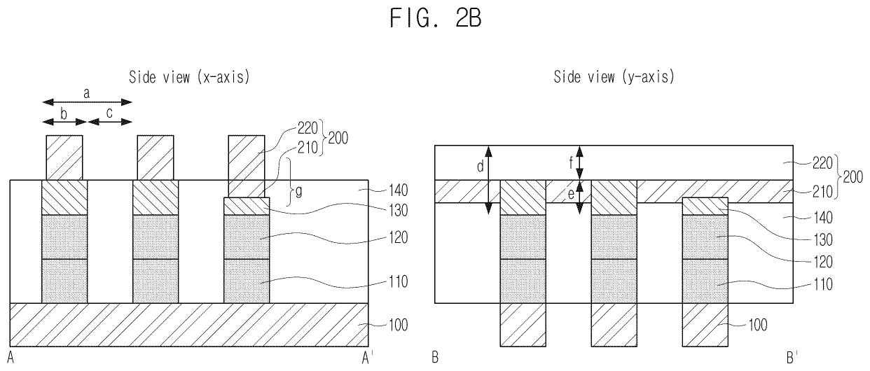

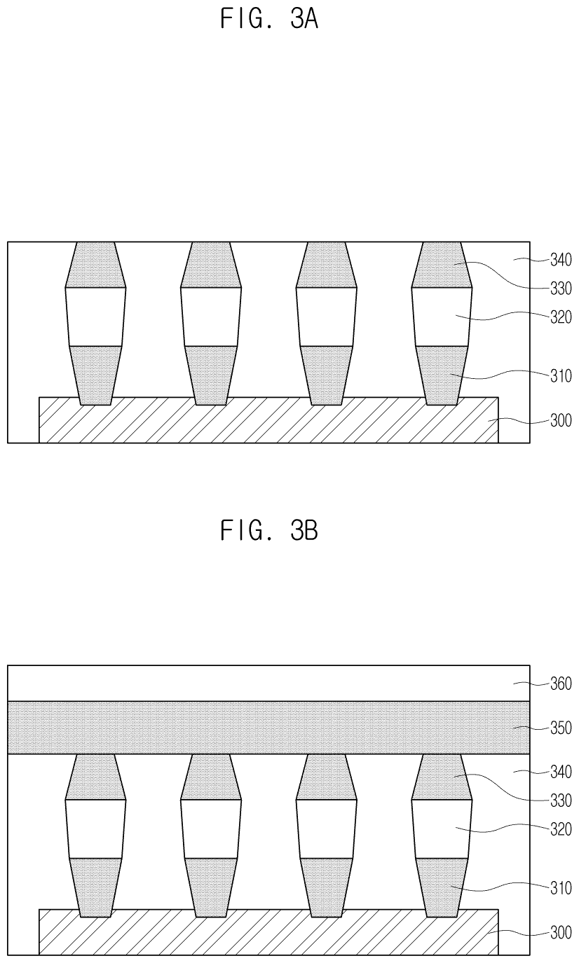

FIG. 1A is a top view illustrating a semiconductor device according to a comparative example. FIG. 1B is a side view of the semiconductor device taken along a line A-A′ shown in FIG. 1A. FIG. 1C is a side view of the semiconductor device taken along a line B-B′ shown in FIG. 1A. Hereinafter, for the sake of convenience in description, a direction substantially parallel to the line A-A′ may be referred to as a first direction, and a direction substantially parallel to the line B-B′ (see FIG. 2A) intersecting with the line A-A′ may be referred to as a second direction.

Referring to FIGS. 1A and 1B, the semiconductor device according to the comparative example may include a plurality of first conductive lines 100 disposed over a substrate (not shown). The semiconductor device according to the comparative example may also include a plurality of second conductive lines 200 disposed over the first conductive lines 100. The first conductive lines 100 are spaced apart from each other in the second direction while extending in the first direction. The second conductive lines 200 are spaced apart from each other in the first direction while extending in the second direction. The device further includes a stacked structure of a selector pattern 110, a Magnetic Tunnel Junction (MTJ) pattern 120 and a hard mask pattern 130 respectively overlapping with the intersection areas between the first conductive lines 100 and the second conductive lines 200, and an inter-layer dielectric layer 140 covering sidewalls of the selector pattern 110, the MTJ pattern 120, and the hard mask pattern 130. Although an embodiment of the present disclosure shows a structure in which the MTJ pattern 120 is formed in the upper portion of the selector pattern 110, the concept and scope of the present invention disclosure are not limited thereto, and the MTJ pattern 120 may be disposed in the upper portion or lower portion of the selector pattern 110.

Referring to FIG. 1B, the sum of the width b of the second conductive line 200 (also referred to as metal line 200) and the gap c between the second metal lines 200 may be a unit cell pitch a. The cell pitch a may indicate the width of a unit cell in which the second metal lines 200 are disposed at a predetermined gap, and it may be a distance designed to minimize the interference from other cells. When the width b of the second metal line 200 is increased to lower the resistance, the current flow may be improved, but when it becomes too wide, the gap c between the neighboring metal lines may be decreased, which may cause a bridging failure between the lines. The bridging failure may cause an electrical short between the neighboring lines, which may cause a circuit error. When the gap c between the metal lines is too narrow, the electrical interference between the lines may increase. Particularly, when the width b of the metal lines is increased, the gap c between the metal lines may become narrow, which increases the probability that a bridging failure may occur between the lines.

Referring to FIG. 1C, first, a fabrication method may be described.

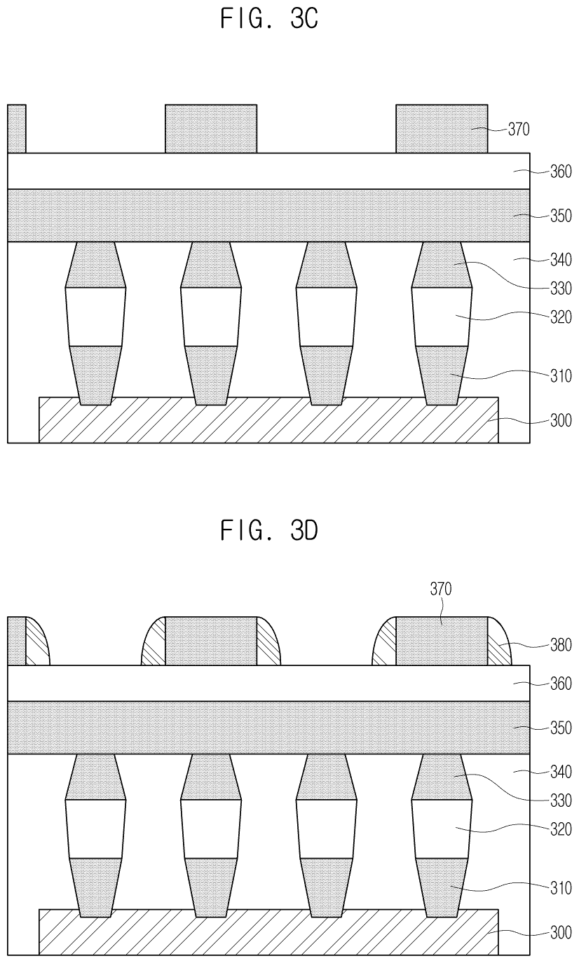

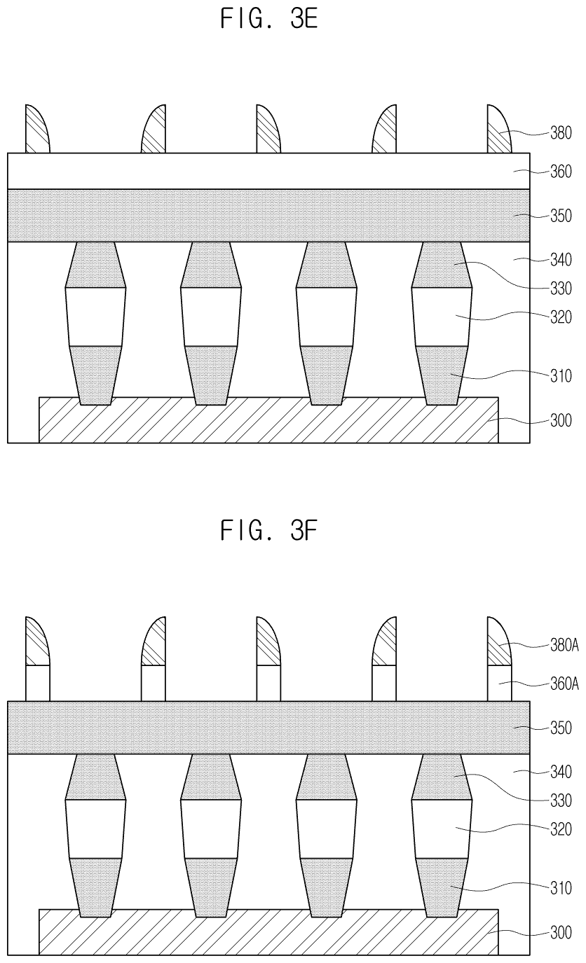

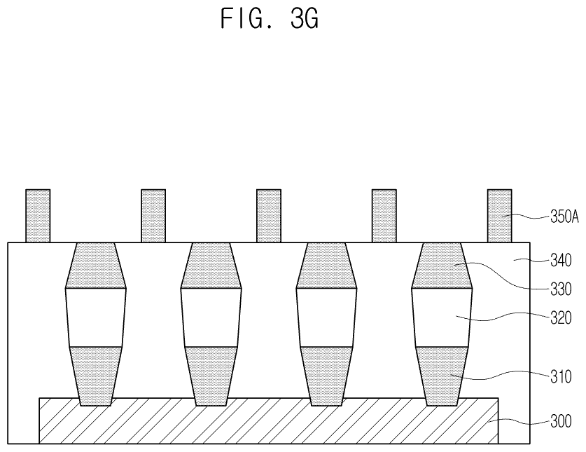

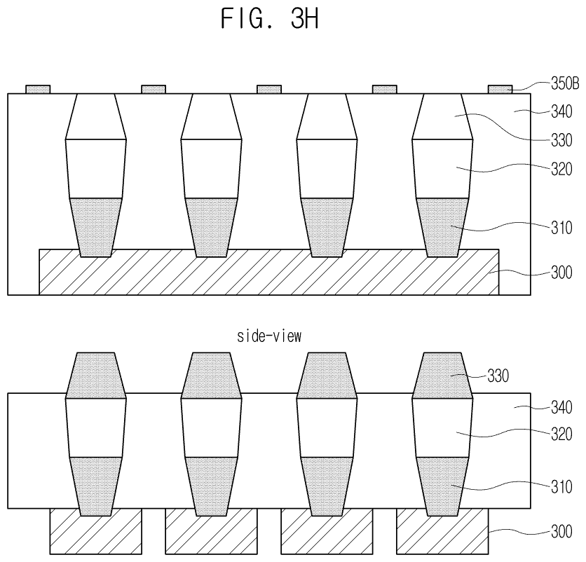

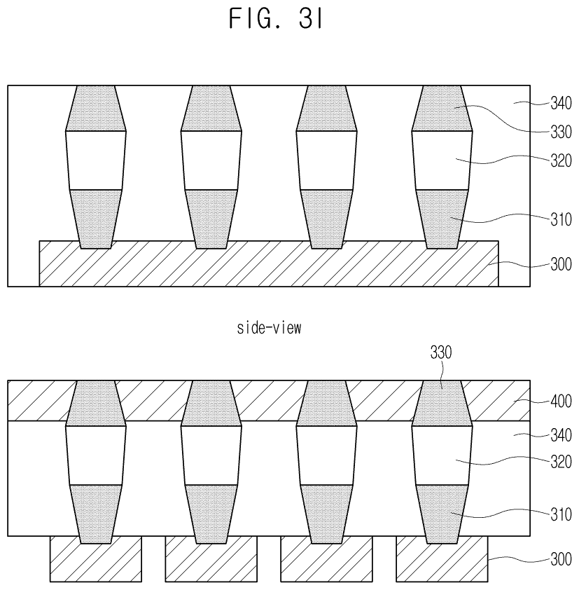

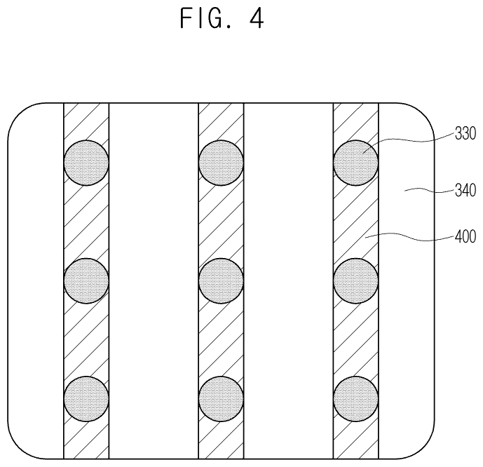

According to this comparative example, a plurality of second conductive lines 250 extending in the second direction and disposed spaced apart from each other in the first direction may be formed by forming a metal layer and a hard mask layer over a stacked structure including a first conductive line 200, a metal contact pattern 210, a selector pattern 220, and an MTJ pattern 230, forming a hard mask pattern, and etching the metal layer with the hard mask pattern used as an etching barrier. Accordingly, the second conductive lines 250 may be formed over the MTJ patterns 230, which is different from the semiconductor device in accordance with an embodiment of the present disclosure in which a plurality of second conductive lines (see element 400 of FIG. 3I) described below are formed between the MTJ patterns (see element 330 of FIG. 3I).

In the semiconductor device according to this comparative example, when the remaining amount of the hard mask 130 in the upper portion of the unit cell is insufficient, a spacing g may be created between the hard mask 130 and the second metal line 200, which may cause an electrical open failure. When the hard mask 130 is insufficient, the hard mask 130 and the second metal line 200 may not electrically contact each other (i.e., referred to as being electrically open), which causes what is referred to as an open failure. This may block off the current flow or cause malfunction, deteriorating the reliability of the cell.

FIG. 2A is a top view illustrating a semiconductor device in accordance with an embodiment of the present disclosure. FIG. 2B is a side view illustrating the semiconductor device in accordance with the embodiment of the present disclosure.

Referring to FIGS. 2A and 2B, the memory device in accordance with the embodiment of the present disclosure may include a substrate (not shown), a plurality of first metal lines 100 disposed over the substrate 100 spaced apart from each other in the second direction while extending in the first direction, a plurality of second metal lines 200 disposed over the first metal lines 100 spaced apart from each other in the first direction while extending in the second direction, a stacked structure of a selector pattern 110, an MTJ pattern 120, and a hard mask pattern 130 respectively overlapping with the intersection areas between the first conductive lines 100 and the second conductive lines 200, and an inter-layer dielectric layer 140 suitable for covering the sidewalls of the selector pattern 110, the MTJ pattern 120, and the hard mask pattern 130.

The substrate may include a semiconductor material, such as silicon. Although not illustrated, the substrate may include a required predetermined lower structure, for example, a driving circuit that is electrically connected to the first conductive lines 100 and/or the second conductive lines 200 to drive the first conductive lines 100 and/or the second conductive lines 200.

Referring to FIG. 2B, the figure on the left side is a side view taken along the x-axis of FIG. 2A, that is, a line A-A′, and the figure on the right side is a side view taken along the y-axis of FIG. 2A, that is, a line B-B′.

In the semiconductor device in accordance with the embodiment of the present disclosure, a recess pattern may be locally formed between the MTJ patterns 120 by using a gap-fill oxide or an etchant having a high etching selectivity.

Referring to the side view taken along the line A-A′, the semiconductor device in accordance with the embodiment of the present disclosure may have the same unit cell pitch a as the unit cell pitch a of the semiconductor device according to the comparative example of FIG. 1B. However, since the semiconductor device in accordance with the embodiment of the present disclosure has a narrower width b of the metal line and a wider gap c between the metal lines than those of the semiconductor device according to the comparative example of FIG. 1B, the probability that the bridging failure may occur between the lines may be significantly decreased. Since the second metal line 200 is formed between the MTJ patterns 120, even though the remaining amount of the hard mask 130 is insufficient, a spacing g does not occur between the second metal line 200 and the hard mask 130. Therefore, an electrical open failure may not be caused.

Referring to the side view taken along the line B-B′, the total height d of the second conductive line 200 may be the sum of the height e of a first second conductive line 210 and the height f of a second second conductive line 220. The second conductive line 200 is designed to be formed between the MTJ patterns 120 and not to cause an electrical open failure. First, the first second conductive line 210 may be formed by forming a first recessed pattern having the height e of the first second conductive line 210 locally between the MTJ patterns 120 by using a gap-fill oxide or an etchant having a high etching selectivity, and filling the first recessed pattern with a metal gap-fill material. Subsequently, the second second conductive line 220 may be formed by forming a second recess pattern having the height f of the second second conductive line 220 over the first second conductive line 210, and filling the second recess pattern with a metal gap-fill material.

A semiconductor device in accordance with an embodiment of the present disclosure and a fabrication method thereof will be described with reference to FIGS. 3A to 3I below.

First, the fabrication method is described.

Referring to FIG. 3A, a stacked structure including a first conductive line 300, a metal contact pattern 310, a selector pattern 320, an MTJ pattern 330, and an inter-layer dielectric layer 340 covering the first conductive line 300, the metal contact pattern 310, the selector pattern 320 and the MTJ pattern 330 may be provided. The upper surface of the stacked structure may be subjected to a Chemical Mechanical Polishing (CMP) process to secure a planar surface for reducing defects and forming a precise pattern in the subsequent process.

The first conductive line 300 may be formed by forming a gap-fill layer (not shown) having a trench for forming the first conductive line 300 over a predetermined structure and depositing a conductive layer for forming the first conductive line 300 in the trench. The first conductive line 300 may include diverse conductive materials, for example, metals such as platinum (Pt), tungsten (W), aluminum (Al), copper (Cu), tantalum (Ta) and the like, metal nitrides such as titanium nitride (TiN), tantalum nitride (TaN) and the like, or combinations thereof, and the first conductive line 300 may have a single-layer structure or a multi-layer structure.

The metal contact pattern 310 disposed over the first conductive line 300 may provide electrical connection between the first conductive line 300 and the selector pattern 320 and the MTJ pattern 330, and the metal contact pattern 310 may be formed of diverse metals or metal nitrides to optimize the stability and electrical characteristics of the stacked structure. To be specific, the metal contact pattern 310 may include tungsten (W), titanium (Ti), titanium nitride (TiN), tantalum (Ta), tantalum nitride (TaN), cobalt (Co), or aluminum (Al). The metal contact pattern 310 may minimize the increase in resistance or formation of an oxide that may occur at the inter-layer coupling portion of the stacked structure. Also, the metal contact pattern 310 may be formed to have a multi-layer structure. For example, by combining a diffusion barrier layer and a conductive layer through the multi-layer structure such as Ti/TiN or Ta/TaN, it is possible to secure the electrical characteristics and durability at the same time.

The selector pattern 320 may be realized as a thin layer in the memory cell and may prevent current leakage that may occur between the memory cells MC that share the first conductive line 300 or the second conductive line (400 of FIG. 3I), while controlling the electrical access to one memory cell among the arrayed memory cells. To this end, the selector pattern 320 may have the threshold switching characteristics of blocking off the current or holding the current to hardly flow when the level of the voltage supplied to the upper and lower portions of the selector pattern 320 is lower than a predetermined threshold voltage level and then letting the current flow rapidly when the voltage level is equal to or higher than the threshold voltage level. The selector pattern 320 may be turned on at a voltage level equal to or higher than the threshold voltage level and turned off at a voltage level lower than the threshold voltage level. For example, the selector pattern 320 may include a dielectric material into which a dopant is implanted.

The MTJ pattern 330 may include a free layer, a tunnel barrier layer, and a fixed layer. Here, the free layer may be a layer that may store different data by having a changeable magnetization direction, and the free layer may also be called a storage layer. The fixed layer may be a layer that may be contrasted with the magnetization direction of the free layer by having a fixed magnetization direction, and the fixed layer may also be called a reference layer. The free layer and the fixed layer may have a single-layer structure or a multi-layer structure including a ferromagnetic material. For example, the free layer and the fixed layer may include an alloy mainly containing Fe, Ni or Co, such as an Fe—Pt alloy, a Fe—Pd alloy, a Co—Pd alloy, a Co—Pt alloy, a Fe—Ni—Pt alloy, a Co—Fe—Pt alloy, a Co—Ni—Pt alloy, a Fe—Pd alloy, a Co—Pd alloy, a Co—Pt alloy, a Fe—Ni—Pt alloy, a Co—Fe—Pt alloy, a Co—Ni—Pt alloy, a Co—Fe—B alloy, or the like, or may include a stacked structure such as Co/Pt, Co/Pd, and the like. The magnetization directions of the free layer and the fixed layer may be substantially perpendicular to the layer surfaces. The magnetization direction of the free layer may vary between the top-down direction and the bottom-up direction, and the magnetization direction of the fixed layer may be fixed in the top-down direction or the bottom-up direction. The magnetization direction of the free layer may be changed due to spin transfer torque. The relative positions of the free layer and the fixed layer may vary diversely with the tunnel barrier layer interposed therebetween. For example, the fixed layer may be disposed below the tunnel barrier layer, and the free layer may be disposed over the tunnel barrier layer. The tunnel barrier layer may enable tunneling of electrons between the free layer and the fixed layer during a write operation that changes the resistance state of a variable resistance element, thereby changing the magnetization direction of the free layer. The tunnel barrier layer may include a dielectric oxide, such as magnesium oxide (MgO), calcium oxide (CaO), strontium oxide (SrO), titanium oxide (TiO), vanadium oxide (VO), niobium oxide (NbO), and the like. The free layer, the tunnel barrier layer, and the fixed layer may form an MTJ structure.

The variable resistance layer including the MTJ patterns 330 may function to store data in diverse ways. For example, the variable resistance layer may include a memory layer that stores different data by switching between different resistance states according to the voltage or current supplied through the upper and lower portions of the variable resistance layer. The memory layer may have a single-layer structure or a multi-layer structure including diverse materials used in a Resistive Random Access Memory (RRAM), a Phase-change Random Access Memory (PRAM), a Ferroelectric Random Access Memory (FRAM), a Magnetic Random Access Memory (MRAM) and the like, for example, metal oxides such as transition metal oxides and perovskite-based materials, phase-change materials such as chalcogenide-based materials, ferroelectric materials, ferromagnetic materials, and the like.

The etching selectivity of the inter-layer dielectric layer 340 may be higher than the etching selectivity of the MTJ patterns 330. For example, the inter-layer dielectric layer 340 may include aluminum oxide (Al₂O₃), titanium oxide (TiO₂), hafnium oxide (HfO₂), zirconium oxide (ZrO₂), or a combination thereof. These materials may provide a high etching selectivity with respect to the MTJ patterns 330 to facilitate the formation of a precise pattern in which only a predetermined material is etched. Since the MTJ pattern 330 is formed of a material having a relatively high etching resistance and the inter-layer dielectric layer 340 is formed of a material having a high etching rate, it is possible to perform patterning into a desired shape by effectively removing the inter-layer dielectric layer 340 while minimizing the influence on the MTJ pattern 330. As the etching selectivity of the inter-layer dielectric layer 340 becomes higher, unnecessary etching of other important structures may be reduced while a target material is etched. This may increase the process stability.

The upper surface of the stacked structure may be subjected to a Chemical Mechanical Polishing (CMP) process to secure a planar surface for reducing defects and forming a precise pattern in the subsequent process.

Referring to FIG. 3B, a first hard mask layer 350 and a second hard mask layer 360 may be sequentially formed over the process structure of FIG. 3A. The first and second hard mask layers 350 and 360 may be formed through a Chemical Vapor Deposition (CVD) process, a Physical Vapor Deposition (PVD) process, or an Atomic Layer Deposition (ALD) process. The first hard mask layer 350 may include silicon nitride (Si₃N₄), silicon oxide (SiO₂), aluminum oxide (Al₂O₃), titanium nitride (TiO₂), or a combination thereof, and the second hard mask layer 360 may include silicon oxide (SiO₂), silicon carbide (SiC), tantalum nitride (TiN), or a combination thereof.

The first and second hard mask layers 350 and 360 may be formed of the same material. The first and second hard mask layers 350 and 360 may be formed of different materials. Preferably, the first and second hard mask layers 350 and 360 may be formed of different materials having different etching selectivities to form a more precise structure. The multi-layer hard mask structure may accurately protect a desired portion in a predetermined process and prevent unnecessary damage, reducing defects that may occur during the process. Preferably, the etching selectivity of the second hard mask layer 360 disposed in the upper position may be higher than the etching selectivity of the first hard mask layer 350 disposed in the lower position so that the second hard mask layer 360 may be selectively etched and the first hard mask layer 350 remains.

Referring to FIG. 3C, a photoresist pattern 370 may be formed over the second hard mask layer 360. First, a liquid photoresist may be applied to the second hard mask layer 360 in a uniform thickness, and then a spin-coating technique may be used to obtain the uniform layer thickness. To form a desired pattern in the photoresist, the photoresist may be exposed to UV light through a mask, and the exposed photoresist may be exposed to a developer solution to remove the exposed or unexposed portions. As a result, the photoresist pattern 370 may be formed. Subsequently, to increase the stability of the photoresist pattern 370, the photoresist pattern 370 may be cured at a low temperature to remove the residual chemicals.

Referring to FIG. 3D, after the formation of the photoresist pattern 370, a process of forming a spacer 380 on both sidewalls of the photoresist pattern 370 may be performed. To form the spacer 380 along the sidewall of the photoresist pattern 370, a thin dielectric layer or an oxide layer, for example, silicon oxide (SiO₂), silicon nitride (Si₃N₄) and the like, may be deposited in a uniform thickness. Here, an Atomic Layer Deposition (ALD) process or a Chemical Vapor Deposition (CVD) process may be used, and the deposition thickness may be adjusted to form the spacer 380 in an appropriate thickness on both sidewalls of the photoresist pattern 370. An isotropic etching process may be performed by using the formed spacer material so that the spacer 380 remains only on both sidewalls of the photoresist pattern 370. This etching process may remove the material deposited on the upper and lower surfaces, leaving the spacer 380 only on the vertical wall surface.

Referring to FIG. 3E, only the photoresist pattern 370 of the structure of FIG. 3D may be selectively etched and removed while leaving only the spacer 380 on the second hard mask layer 360. The photoresist pattern 370 may be removed by using a chemical agent or by performing a plasma strip process. As a result, the remaining spacer structure may be fixed over the second hard mask layer 360, and only the photoresist pattern 370 may be removed.

The chemical agent removal method may include a wet etching technique using a chemical solution that melts or dissolves the photoresist pattern 370. For example, a strongly basic solution or a strongly acidic solution may be used. For example, the chemical agent may be a Piranha solution in which sulfuric acid and hydrogen peroxide are mixed with each other or N-methyl-2-pyrrolidone (NMP). By using the chemical agent, the photoresist pattern 370 may be effectively dissolved to be completely removed from the substrate. Also, since the chemical agent selectively acts only on a predetermined area by controlling the process time and temperature appropriately, the photoresist pattern 370 may be removed without damaging the second hard mask layer 360 and the spacer 380.

A plasma strip process may include a dry etching technique that removes the photoresist pattern 370 by using a plasma chemical reaction, and oxygen plasma may be used. The oxygen plasma may chemically react with the photoresist pattern 370 to transform the photoresist pattern 370 into a gaseous state. Since plasma may cause a reaction without maintaining a high temperature, it may minimize the damage to the second hard mask layer 360 and the spacer 380, and thus it is more effective even for a sensitive fine structure. The plasma strip method may be advantageous in that it not only completely removes any residual of the photoresist pattern 370 but also has an additional cleaning effect of removing the impurities or organic substances after the process.

When the photoresist pattern 370 is completely removed through this method of removing the photoresist pattern 370, only the spacer 380 structure may remain fixed over the second hard mask layer 360. This spacer 380 may serve as a guide to form a predetermined pattern in the second hard mask layer 360 through an etching process in a subsequent operation, and may facilitate accurate formation of a fine structure.

The spacer 380 may be formed of a material having excellent corrosion resistance and heat resistance and may include, for example, carbon nitride (SiCN), silicon nitride (Si₃N₄), hafnium nitride (HfN), or zirconium nitride (ZrN). Also, the spacer 380 may be formed by combining nitride and oxide in a multi-layer structure.

Referring to FIG. 3F, the second hard mask layer 360 may be selectively etched by using the spacer 380 as an etching barrier to form a second hard mask pattern 360A and a spacer pattern 380A over the second hard mask pattern 360A. In this process, the spacer 380 may serve as a barrier to prevent etching during the etching process so that the second hard mask layer 360 in the portion where the spacer 380 is not disposed is removed, and only the portion of the hard mask layer 360 over which the spacer 380 is disposed may remain.

The etching process using the spacer 380 as etching barrier may include a dry etching method, and the second hard mask layer 360 may be selectively etched through this etching method. The portions of the second hard mask layer 360 where the spacer 380 is not disposed may be removed by the etching process. As a result, the second hard mask layer 360 may remain only in the area where the spacer 380 is disposed, and may be transformed into the second hard mask pattern 360A. When the etching process is completed, the spacer 380 may be partially etched and transformed into the spacer pattern 380A. The spacer pattern 380A and the hard mask pattern 360A may exist in an area where the MTJ pattern 330 is not disposed underneath. The spacer pattern 380A and the hard mask pattern 360A may be disposed in the areas overlapping the gaps between the MTJ patterns 330, and the spacer pattern 380A and the hard mask pattern 360A may not overlap with the MTJ patterns 330. Therefore, only the first hard mask layer 350 in the upper portion of the MTJ pattern 330 may be selectively etched in the process described below.

Referring to FIG. 3G, the first hard mask pattern 350A may be formed by using the spacer pattern 380A and the second hard mask pattern 360A as etching barriers and selectively etching the first hard mask layer 350 over the MTJ pattern 330. This process may etch the first hard mask layer 350 until the upper surface of the MTJ pattern 330 is exposed, and finally, only the first hard mask pattern 350A may remain, and the spacer pattern 380A and the second hard mask pattern 360A may all be removed. In this operation, the etching depth may be precisely controlled to expose only the upper surface of the MTJ pattern 330 and protect the remaining MTJ and peripheral structures from being damaged. After the upper surface of the MTJ pattern 330 is exposed, the spacer pattern 380A and the second hard mask pattern 360A may be removed, thereby enabling electrical connection of the MTJ and formation of an additional pattern in the subsequent process.

Referring to FIG. 3H, a deep and selective etching process that reaches near the lower surface of the MTJ pattern 330 may be performed by selectively etching the inter-layer dielectric layer 340 between the MTJ patterns 330. The etching selectivity of the inter-layer dielectric layer 340 may be higher than the etching selectivity of the MTJ patterns 330. For example, the inter-layer dielectric layer 340 may include aluminum oxide (Al₂O₃), titanium oxide (TiO₂), hafnium oxide (HfO₂), zirconium oxide (ZrO₂), or a combination thereof. These materials may provide a high etching selectivity with respect to the MTJ patterns 330 to facilitate the formation of a precise pattern in which only a predetermined material is etched. Since the MTJ patterns 330 have relatively high etching resistance and the inter-layer dielectric layer 340 is formed of a material having a high etching rate, it is possible to perform patterning into a desired shape by effectively removing the inter-layer dielectric layer 340 while minimizing the influence on the MTJ patterns 330.

The selective etching process onto the inter-layer dielectric layer 340 between the MTJ patterns 330 may be performed by a Reactive Ion Etching (RIE) process, an inert gas plasma process, or a Chemically Assisted Etching process. The RIE process may be used for an etching process with a high selectivity. The RIE process may be performed by transforming gas into a plasma state and making the ions collide with the area between the MTJ patterns 330 and the inter-layer dielectric layer 340. Herein, by using a predetermined gas to induce a selective reaction with the MTJ patterns 330, it is possible to minimize the damage to the MTJ structure while removing a portion of the inter-layer dielectric layer 340. When the inter-layer dielectric layer 340 includes aluminum oxide (Al₂O₃), then hydrogen fluoride (HF) or carbon tetrafluoride (CF₄) may be used as the etching gas. When the inter-layer dielectric layer 340 includes titanium oxide (TiO₂), then carbon tetrafluoride (CF₄) or chlorine (Cl₂) gas may be used as the etching gas. When the inter-layer dielectric layer 340 includes hafnium oxide (HfO₂), then chlorine (Cl₂) gas, fluorine (F₂) gas, or boron trichloride (BCl₃) may be used as the etching gas.

Also, the inter-layer dielectric layer 340 may be physically selectively removed using an inert gas. Since this method allows a soft etching process, the damage to the MTJ patterns 330 may be minimized. Also, the inter-layer dielectric layer 340 may be selectively removed without damaging the MTJ patterns 330 by using a predetermined chemical agent and performing a chemically assisted etching process. According to this method, the etching rate may be controlled by adjusting the concentration of the chemical agent.

The etching process may be performed until the vicinity of the lower surface of the MTJ pattern 330 is etched by selectively etching the inter-layer dielectric layer 340 between the MTJ patterns 330. After the etching process is completed, a portion of the first hard mask pattern may remain to form a residual pattern 350B.

Referring to FIG. 3I, a second conductive line 400 may be formed by filling the etched portion between the MTJ patterns 330 with a metal gap-fill material. The second conductive line 400 may be formed by performing a Chemical Vapor Deposition (CVD) process or a Physical Vapor Deposition (PVD) process with the metal gap-fill material.

The metal gap-fill material may include diverse conductive metals, such as tungsten (W), copper (Cu), aluminum (Al), or alloys thereof, each of which may provide high conductivity and appropriate physical properties. In particular, tungsten (W) may be appropriate for the MTJ structure because tungsten (W) maintains stability even at a high temperature. After filling the metal gap-fill material, the residual pattern 350B may be completely removed and the upper surface of the process structure may be planarized through a Chemical Mechanical Polishing (CMP) process. The CMP process may increase the uniformity of the surface and minimize the height difference between the patterns, and maximize the reliability and performance of the conductive structure that is finally formed through this process.

The second conductive line 400 may also be formed of diverse conductive materials, for example, platinum (Pt), tungsten (W), aluminum (Al), copper (Cu), tantalum (Ta), titanium nitride (TiN), tantalum nitride (TaN), and combinations thereof. The selection of these diverse materials may be optimized according to the process conditions and electrical requirements. Also, the upper surface of each of the second conductive lines may be disposed at a level equal to or lower than the upper surface of each MTJ pattern, thereby maintaining the electrical connection more stably. This structure may contribute to improving the performance of the MTJ element and increasing the reliability of a cell.

The semiconductor device in accordance with the embodiment of the present disclosure, as illustrated in FIG. 3I, may be fabricated by the process described above.

Referring back to FIG. 3I, the semiconductor device in accordance with the embodiment of the present disclosure may include the first conductive line 300, the metal contact pattern 310, the selector pattern 320, the MTJ pattern 330, and the inter-layer dielectric layer 340 covering the first conductive line 300, the metal contact pattern 310, the selector pattern 320, the MTJ pattern 330. Also, the semiconductor device in accordance with the embodiment of the present disclosure may include the second conductive line 400 (see also FIG. 4) that is formed not over the MTJ pattern 330 but formed between the sidewalls of the MTJ patterns 330.

According to the semiconductor device in accordance with the embodiment of the present disclosure, the width of each second metal line 400 may be reduced, and at the same time, the gap between the second metal lines 400 is widened. Therefore, the probability that a bridging failure occurs between the lines may be significantly reduced. To be specific, since the second metal line 400 is formed to have a narrow width, the interference between the metals may be minimized, and thus, the electrical signal interference and short between the second metal lines 400 may be prevented. Also, as the gap between the second metal lines 400 becomes wide, the possibility of the formation of an unnecessary bridge may be significantly reduced, ensuring stable operation characteristics.

Also, since the second metal line 400 is formed between the MTJ patterns 330, even though the remaining amount of the hard mask is insufficient, there may be no gap between the second metal lines 400 and the hard mask. As a result, the second metal lines 400 may be maintained to be tightly close to each other. Therefore, an electrical open failure may not occur, and the high reliability of the device may be maintained.

The semiconductor device in accordance with the embodiment of the present disclosure may further include a first electrode layer and a second electrode layer respectively disposed in the lower portion and the upper portion of the selector pattern 320, and may further include a third electrode layer in the upper portion of the MTJ pattern 330. The first electrode layer and the third electrode layer may be respectively disposed at both ends of the memory cell, that is, in the lower and upper portions of the memory cell, to transfer a voltage or current required for an operation of the memory cell. The second electrode layer may function to electrically connect the selector pattern 320 and the MTJ pattern 330 while physically separating them from each other. The first electrode layer, the second electrode layer, or the third electrode layer may include diverse conductive materials, for example, metals such as platinum (Pt), tungsten (W), aluminum (Al), copper (Cu), tantalum (Ta), titanium (Ti) and the like, metal nitrides such as titanium nitride (TiN), tantalum nitride (TaN) and the like, or combinations thereof. Also, the first electrode layer, the second electrode layer, or the third electrode layer may include a carbon electrode.

The first electrode layer and the second electrode layer may include diverse conductive materials, such as metals, metal nitrides, or the like. The first electrode layer and the second electrode layer may be formed of the same material, and thus, may have the same work function. For example, the first electrode layer and the second electrode layer may include titanium nitride (TiN) having a work function of approximately 4.4 to 4.6 eV. However, the concept and scope of the present disclosure are not limited thereto, and the first electrode layer and the second electrode layer may be formed of different materials to have different work functions. The second electrode layer may be realized as a single TiN thin layer, or may be realized by stacking a carbon (C) thin layer and a TiN layer. For example, the second electrode layer over the selector pattern 320 may include tungsten (W), titanium nitride (TiN), tantalum (Ta), molybdenum (Mo), or copper (Cu). Also, a SiN thin layer may be formed between the first electrode layer and the selector pattern 320, and a carbon (C) thin layer may be formed between the selector pattern 320 and the second electrode layer. The third electrode layer may be formed over the second electrode layer and the MTJ pattern 330, and may be generally formed of a material that may withstand a high-temperature heat treatment and have excellent conductivity. The third electrode layer may be formed by performing a metal deposition process or a sputtering method. To be specific, the third electrode layer may be formed by depositing a conductive metal thin layer, such as platinum (Pt), ruthenium (Ru), cobalt (Co), nickel (Ni), or iridium (Ir). The third electrode layer formed over the MTJ patterns 330 may include platinum (Pt), ruthenium (Ru), cobalt (Co), nickel (Ni), or iridium (Ir).

According to the embodiment of the present disclosure, the stacked structure of the metal contact pattern 310, the selector pattern 320, and the MTJ pattern 330 may be patterned together to have sidewalls that are aligned with each other. Furthermore, the stacked structure of the metal contact pattern 310, the selector pattern 320, and the MTJ pattern 330 may have a square pillar shape having both sidewalls aligned with both sidewalls of the second conductive line 400 in the first direction, and both sidewalls aligned with both sidewalls of the first conductive line 300 in the second direction. However, the concept and scope of the present disclosure are not limited thereto, and the sidewalls of the metal contact pattern 310, the selector pattern 320, and the MTJ pattern 330 may not be aligned with each other. Also, the sidewalls of the metal contact pattern 310, the selector pattern 320, and the MTJ pattern 330 may be aligned with each other but may not be aligned with the sidewalls of the first conductive line 300 and/or the second conductive line 400.

When the metal contact pattern 310, the selector pattern 320 and the MTJ pattern 330 are formed, the etching by-products originating from the etching target may be re-deposited on the sidewalls thereof. As a result, spacers originating from the etching by-products may be formed on the sidewalls of the patterns. These spacers may include carbon (C), aluminum oxide (Al₂O₃), titanium oxide (TiO₂), or tantalum oxide (Ta₂O₅).

FIG. 4 is a top view illustrating a semiconductor device in accordance with an embodiment of the present disclosure. The inter-layer dielectric layer 340 surrounding the MTJ patterns 330 may be formed of a material whose etching selectivity is higher than the etching selectivity of the MTJ patterns 330. This may allow a predetermined region between the MTJ patterns 330 to be effectively patterned by selectively removing the inter-layer dielectric layer 340 while minimizing the damage to the MTJ patterns 330. The inter-layer dielectric layer 340 may include, for example, aluminum oxide (Al₂O₃), titanium oxide (TiO₂), hafnium oxide (HfO₂), zirconium oxide (ZrO₂), or a combination thereof. The high-selectivity dielectric material may be able to protect the MTJ patterns 330 and to form a recess region deeper than the etched portion between the MTJ patterns 330 because the etching selectivity of the high-selectivity dielectric material is different from the etching selectivity of the MTJ patterns 330. This recess region may be filled with a metal gap-fill material, enabling the second conductive line 400 to be formed stably in a subsequent process. This structure may contribute to improving the reliability of the semiconductor device by optimizing the electrical connection and maintaining the structural stability of the MTJ patterns.

According to the embodiment of the present disclosure, it is possible to effectively eliminate line-to-line bridging failures that may occur in a crosspoint structure and to effectively eliminate the possibility of the electrical open failures in the semiconductor device, and a method for fabricating the same.

Also, according to the embodiment of the present disclosure, the electrical resistance may be minimized due to the optimal arrangement of the Magnetic Tunnel Junction (MTJ) patterns and the conductive lines in the semiconductor device, and a method for fabricating the same.

While the embodiments of the present invention have been described with respect to specific embodiments, it will be apparent to those skilled in the art that various changes and modifications may be made without departing from the technical concepts and the scope of the present disclosure. Furthermore, the embodiments may be combined to form additional embodiments.

What is claimed is:

1. A semiconductor device comprising:
a plurality of first conductive lines extending in a first direction;
a plurality of second conductive lines disposed over the first conductive lines and extending in a second direction intersecting with the first direction; and
a plurality of memory cells respectively overlapping with intersection areas between the first conductive lines and the second conductive lines,
wherein each of the memory cells includes a selector pattern and a Magnetic Tunnel Junction (MTJ) pattern which is disposed in an upper portion or a lower portion of the selector pattern, and
wherein each of the second conductive lines is disposed between each MTJ pattern.

2. The semiconductor device of claim 1, further comprising
a metal contact pattern over the first conductive lines.

3. The semiconductor device of claim 2, wherein the metal contact pattern includes
tungsten (W), titanium (Ti), titanium nitride (TiN), tantalum (Ta), tantalum nitride (TaN), cobalt (Co), or aluminum (Al).

4. The semiconductor device of claim 1, further comprising
a first electrode layer over the selector pattern.

5. The semiconductor device of claim 4, wherein the first electrode layer includes
tungsten (W), titanium nitride (TiN), tantalum (Ta), molybdenum (Mo), or copper (Cu).

6. The semiconductor device of claim 1, further comprising
a second electrode layer over the MTJ pattern.

7. The semiconductor device of claim 6, wherein the second electrode layer includes
platinum (Pt), ruthenium (Ru), cobalt (Co), nickel (Ni), or iridium (Ir).

8. The semiconductor device of claim 1, wherein an upper surface of each of the second conductive lines is disposed at a level equal to or lower than an upper surface of the MTJ pattern.

9. The semiconductor device of claim 1, further comprising
a spacer disposed over at least a portion of each of a sidewall of the MTJ pattern and a sidewall of the selector pattern, and including carbon (C), aluminum oxide (Al₂O₃), titanium oxide (TiO₂), or tantalum oxide (Ta₂O₅).

10. The semiconductor device of claim 1, wherein the second conductive line includes
platinum (Pt), tungsten (W), aluminum (Al), copper (Cu), tantalum (Ta), titanium nitride (TiN), tantalum nitride (TaN), or a combination thereof.

11. The semiconductor device of claim 1, further comprising
an inter-layer dielectric layer suitable for covering at least a portion of the first conductive lines, the selector pattern, and the MTJ pattern,
wherein an etching selectivity of the inter-layer dielectric layer is higher than an etching selectivity of the MTJ pattern.

12. The semiconductor device of claim 11, wherein the inter-layer dielectric layer includes
aluminum oxide (Al₂O₃), titanium oxide (TiO₂), hafnium oxide (HfO₂), zirconium oxide (ZrO₂), or a combination thereof.

13. A method for fabricating a semiconductor device, the method comprising:
forming a hard mask layer over a plurality of Magnetic Tunnel Junction (MTJ) patterns;
forming a spacer pattern in an upper portion of the hard mask layer;
forming a hard mask pattern by etching the hard mask layer with the spacer pattern used as an etching barrier;
etching between the MTJ patterns by using the hard mask pattern as an etching barrier; and
forming a conductive line by filling the etched portion between the MTJ patterns with a metal gap-fill material.

14. The method of claim 13, wherein forming the spacer pattern includes:
forming a photoresist pattern in an upper portion of the hard mask layer;
forming a spacer on a sidewall of the photoresist pattern; and
selectively etching the photoresist pattern.

15. The method of claim 13, wherein in forming the hard mask pattern,
the etching process is performed until upper surfaces of the MTJ patterns are exposed.

16. The method of claim 13, wherein forming the conductive line is performed by filling a metal gap-fill material through a Chemical Vapor Deposition (CVD) process or a Physical Vapor Deposition (PVD) process.

17. The method of claim 13, wherein the metal gap-fill material includes
tungsten (W), copper (Cu), aluminum (Al), or an alloy thereof.

18. The method of claim 13, wherein the hard mask layer includes
silicon nitride (Si₃N₄), silicon oxide (SiO₂), aluminum oxide (Al₂O₃), titanium nitride (TiO₂), silicon carbide (SiC), tantalum nitride (TiN), or a combination thereof.

19. The method of claim 13, wherein the spacer pattern includes
carbon nitride (SiCN), silicon nitride (Si₃N₄), hafnium nitride (HfN), or zirconium nitride (ZrN).

20. The method of claim 13, wherein forming the hard mask layer includes
sequentially forming a first hard mask layer and then a second hard mask layer, and
wherein the first hard mask layer and the second hard mask layer include different materials.

21. The method of claim 20, wherein etching selectivities of the first hard mask layer and the second hard mask layer are different from each other.

22. The method of claim 20, wherein the first hard mask layer includes silicon nitride (Si₃N₄), silicon oxide (SiO₂), aluminum oxide (Al₂O₃), titanium nitride (TiO₂), or a combination thereof, and
wherein the second hard mask layer includes silicon oxide (SiO₂), silicon carbide (SiC), tantalum nitride (TiN), or a combination thereof.

23. The method of claim 13, wherein etching between the MTJ patterns is performed by a Reactive Ion Etching (RIE) process, an inert gas plasma process, or a chemically assisted etching process.

24. The method of claim 13, wherein forming the conductive lines includes
performing a Chemical Mechanical Polishing (CMP) process after filling the metal gap-fill material.

25. The method of claim 13, wherein an inter-layer dielectric layer covering the sidewall of each MTJ pattern and including a metal oxide exists between the MTJ patterns, and
wherein an etching selectivity of the inter-layer dielectric layer is higher than an etching selectivity of the MTJ patterns.

26. The method of claim 25, wherein the inter-layer dielectric layer includes
aluminum oxide (Al₂O₃), titanium oxide (TiO₂), hafnium oxide (HfO₂), zirconium oxide (ZrO₂), or a combination thereof.
